(19) United States
(12) Patent Application Publication
(10) Pub. No.: US 2025/0096013 A1
(43) Pub. Date: Mar. 20, 2025

(54) SUBSTRATE PROCESSING APPARATUS AND TREATMENT SOLUTION SUPPLY UNIT

(71) Applicant: SEMES CO., LTD., Cheonan-si (KR)

(72) Inventors: Min Kyoung KIM, Cheonan-si (KR); Jun Kil HWANG, Yongin-si (KR); Hee Hwan KIM, Sejung City (KR)

(73) Assignee: SEMES CO., LTD., Cheonan-si (KR)

(21) Appl. No.: 18/779,707

(22) Filed: Jul. 22, 2024

(30) Foreign Application Priority Data
Sep. 19, 2023 (KR) 10-2023-0124585

(51) Int. Cl. H01L 21/67

(52) U.S. Cl. CPC H01L 21/6708

(57) ABSTRACT

Disclosed is an apparatus for processing a substrate, the apparatus including: a chamber having a processing space for processing a substrate; a support unit disposed in the processing space and for supporting the substrate; a liquid discharge unit for supplying a treatment solution to the substrate and processing the substrate when processing the substrate; and a liquid supply unit for supplying a treatment solution to the liquid discharge unit, in which the liquid supply unit includes: a tank for storing the treatment solution; a liquid supply line for supplying the treatment solution in the tank to the liquid discharge unit; a vent line connected to the tank to discharge water-containing gas in the tank; a heater for heating the treatment solution in the tank or the treatment solution circulating from the tank; and a condensate discharge line connected to the vent line and for discharging condensate generated from the water-containing gas.

### CROSS-REFERENCE TO RELATED APPLICATIONS

This application claims priority to and the benefit of Korean Patent Application No. 10-2023-0124585 filed in the Korean Intellectual Property Office on Sep. 19, 2023, the entire contents of which are incorporated herein by reference.

### TECHNICAL FIELD

The present invention relates to a substrate processing apparatus unit for processing a substrate and a treatment solution supply unit.

### BACKGROUND ART

To manufacture semiconductor devices, various processes, such as photography, deposition, ashing, etching, and ion implantation, are performed. In addition, before and after these processes are performed, a cleaning process of cleaning particles remaining on the substrate is performed.

Among the processes, the etching process is mainly a wet etching process in which a substrate is processed by discharging an etchant onto the substrate, and a dry etching process in which the substrate is plasma treated.

Among the above-mentioned wet etching processes, there is a process in which an aqueous solution of sulfuric acid heated with an etchant is used.

In this case, the heated sulfuric acid is supplied while being stored in a tank, and the heated sulfuric acid is heated and evaporated or naturally evaporated to generate water-containing gas inside the tank. Accordingly, a line is configured to discharge the water-containing gas from the tank, and in this case, the water-containing gas recondenses by the temperature difference between the heated sulfuric acid and the outside air in the process of discharging the water-containing gas through the line, and a condensate is generated upon recondensation.

In this case, the condensate is deposited in the form of droplets in the line that discharges the moisture containing gas and an upper surface of the tank, and thus the condensate falls into a treatment solution inside the tank and is mixed with the treatment solution.

Thus, there is a problem in that the treatment solution mixed with the condensate has increased contamination by particle matter contained in the condensate.

### SUMMARY OF THE INVENTION

The present invention has been made in an effort to provide a substrate processing apparatus and a treatment solution supply unit, in which when the water-containing gas is discharged by vaporization of a treatment solution, mixing of the treatment solution with condensate generated by recondensation of water-containing gas is minimized.

The present invention has also been made in an effort to provide a substrate processing apparatus and a treatment solution supply unit, in which when the water-containing gas is discharged by vaporization of a treatment solution, recondensation of water-containing gas is minimized.

The object of the present invention is not limited thereto, and other objects not mentioned will be clearly understood by those of ordinary skill in the art from the following description.

An exemplary embodiment of the present invention provides an apparatus for processing a substrate, the apparatus including: a chamber having a processing space for processing a substrate; a support unit disposed in the processing space and for supporting the substrate; a liquid discharge unit for supplying a treatment solution to the substrate and processing the substrate when processing the substrate; and a liquid supply unit for supplying a treatment solution to the liquid discharge unit, in which the liquid supply unit includes: a tank for storing the treatment solution; a liquid supply line for supplying the treatment solution in the tank to the liquid discharge unit; a vent line connected to the tank to discharge water-containing gas in the tank; a heater for heating the treatment solution in the tank or the treatment solution circulating from the tank; and a condensate discharge line connected to the vent line and for discharging condensate generated from the water-containing gas.

According to the exemplary embodiment, the vent line may further include a downwardly protruding region that decreases in height as it goes downstream and subsequently increases in height as it goes downstream, and the condensate discharge line may be connected to the vent line in the downwardly protruding region.

According to the exemplary embodiment, the condensate discharge line may be connected to the vent line in a region having the lowest height in the downwardly protruding region.

According to the exemplary embodiment, the vent line may include: a first line connected to the tank; a second line extending from the first line and inclined downwardly in a downstream direction; and a third line extending from the second line and inclined upwardly in a downstream direction, and the condensate discharge line may be connected to the vent line at a point where the second line and the third line are connected.

According to the exemplary embodiment, the first line may be connected to the tank so as to extend upwardly from a top surface of the tank.

According to the exemplary embodiment, the liquid supply unit may further include a gas supply line for supplying gas containing nitrogen gas or inert gas to the tank.

According to the exemplary embodiment, the gas supplied to the tank from the gas supply line may be in a heated state.

According to the exemplary embodiment, the gas supplied to the tank from the gas supply line may have a temperature equal to or higher than a temperature of the treatment solution.

According to the exemplary embodiment, the treatment solution may include a chemical diluted with water.

According to the exemplary embodiment, the chemical may be sulfuric acid or phosphoric acid.

Another exemplary embodiment of the present invention provides a treatment solution supply unit for supplying a treatment solution to process a substrate, the treatment solution supply unit including: a tank for storing the treatment solution; a liquid supply line for supplying a treatment solution in the tank to a liquid discharge unit; a vent line connected to the tank to discharge water-containing gas in the tank; a heater for heating the treatment solution in the tank or the treatment solution circulating from the tank; and a condensate discharge line connected to the vent line to discharge condensate generated from the water-containing gas.

According to the exemplary embodiment, the vent line may further include a downwardly protruding region that decreases in height as it goes downstream and subsequently increases in height as it goes downstream, and the condensate discharge line may be connected to the vent line in the downwardly protruding region.

According to the exemplary embodiment, the condensate discharge line may be connected to the vent line in a region having the lowest height in the downwardly protruding region.

According to the exemplary embodiment, the vent line may include: a first line connected to the tank; a second line extending from the first line and inclined downwardly in a downstream direction; and a third line extending from the second line and inclined upwardly in a downstream direction, and the condensate discharge line may be connected to the vent line at a point where the second line and the third line are connected.

According to the exemplary embodiment, the first line may be connected to the tank so as to extend upwardly from a top surface of the tank.

According to the exemplary embodiment, the liquid supply unit may further include a gas supply line for supplying gas containing nitrogen gas or inert gas to the tank.

According to the exemplary embodiment, the gas supplied to the tank from the gas supply line may be in a heated state.

According to the exemplary embodiment, the treatment solution may include a chemical diluted with water.

According to the exemplary embodiment, the chemical may be sulfuric acid or phosphoric acid.

Still another exemplary embodiment of the present invention provides an apparatus for processing a substrate, the apparatus including: a chamber having a processing space for processing a substrate; a support unit disposed in the processing space and for supporting the substrate; a liquid discharge unit for supplying a treatment solution to the substrate and processing the substrate when processing the substrate; and a liquid supply unit for supplying a treatment solution to the liquid discharge unit, in which the liquid supply unit includes: a tank for storing the treatment solution; a liquid supply line for supplying the treatment solution in the tank to the liquid discharge unit; a vent line connected to the tank to discharge water-containing gas in the tank; a heater for heating the treatment solution in the tank or the treatment solution circulating from the tank; and a condensate discharge line connected to the vent line to discharge condensate generated from the water-containing gas, and the treatment solution is a liquid containing a chemical and moisture, and the vent line includes: a first line connected to the tank; a second line extending from the first line and inclined downwardly toward a downstream direction; and a third line extending from the second line and inclined upwardly in a downstream direction, and the condensate discharge line is connected to the vent line at a point where the second line and the third line are connected.

According to the exemplary embodiment,

The present invention has the effect that when the water-containing gas is discharged by vaporization of the treatment solution, mixing of a treatment solution with condensate generated by recondensation of water-containing gas is minimized.

Further, the present invention has the effect that when the water-containing gas is discharged by vaporization of a treatment solution, recondensation of water-containing gas is minimized.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a top plan view illustrating a substrate processing facility according to an exemplary embodiment of the present invention.

FIG. 2 is a cross-sectional view illustrating a substrate processing apparatus of FIG. 1.

FIG. 3 is a diagram illustrating a liquid supply unit illustrated in FIG. 2 in more detail.

FIG. 4 is an enlarged view of the periphery of a tank illustrated in FIG. 3.

FIG. 5 is a diagram of a modified example of a first line, a second line, and a third line illustrated in FIG. 4.

FIG. 6 is a diagram schematically illustrating a substrate processing apparatus for processing a substrate by using phosphoric acid.

FIG. 7 is a diagram schematically illustrating the substrate processing apparatus illustrated in FIG. 6 further configured with a phosphate buffer tank.

FIG. 8 is a diagram schematically illustrating a sheet-fed type liquid treating chamber of FIG. 6 configured as a batch type liquid treatment chamber.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be treated. However, the technical spirit of the present invention may be applied to devices used for other types of substrate treatment, in addition to wafers.

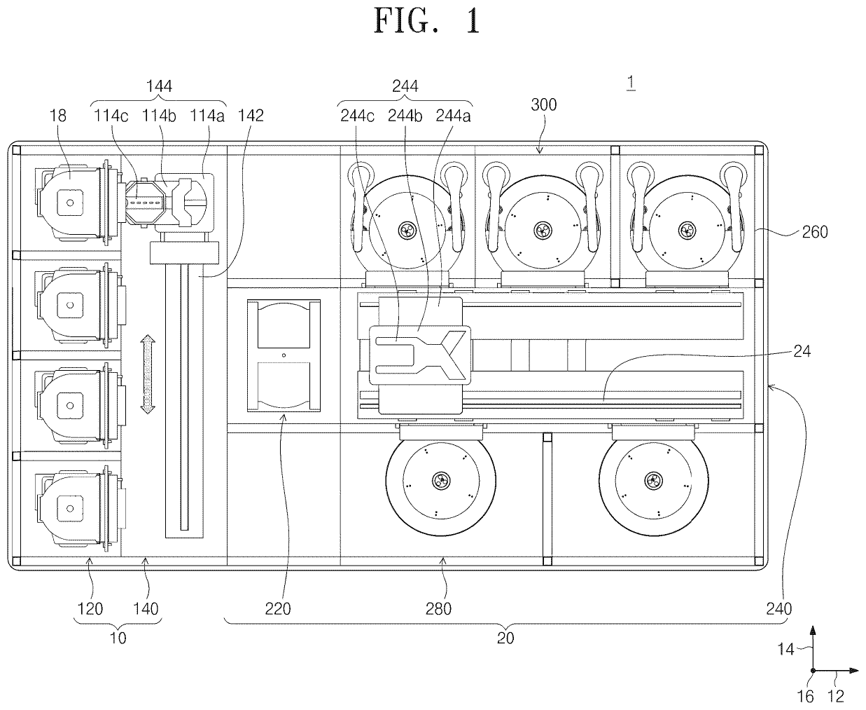

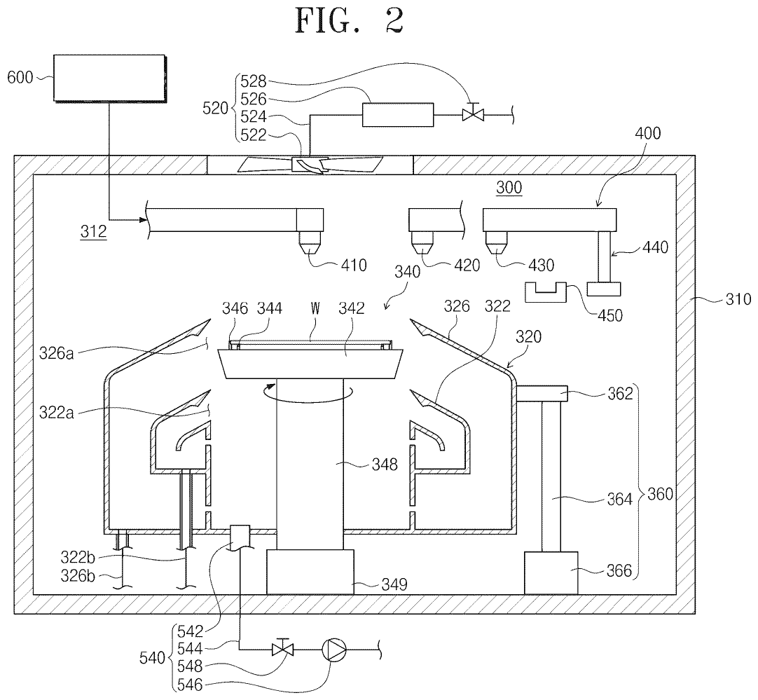

FIG. 1 is a top plan view illustrating a substrate processing facility according to an exemplary embodiment of the present invention. FIG. 2 is a cross-sectional view illustrating a substrate processing apparatus of FIG. 1.

Referring to FIGS. 1 and 2, a substrate processing facility 1 includes an index module 10 and a process processing module 20, and the index module 10 includes a load port 120 and a transfer frame 140. The load port 120, the transfer frame 140, and the process processing module 20 are arranged in sequential rows. Hereinafter, a direction in which the load port 120, the transfer frame 140, and the process processing module 20 are arranged is referred to as a first direction 12, a direction perpendicular to the first direction 12 when viewed from above is referred to as a second direction 14, and a direction perpendicular to a plane including the first direction 12 and the second direction 14 is referred to as a third direction 16.

A carrier 18 in which a substrate W is accommodated is seated on the load port 120. A plurality of load ports 120 is provided, which are arranged in a row along the second direction 14. In FIG. 1, it is illustrated that four load ports 120 are provided. However, the number of load ports 120 may be increased or decreased depending on conditions, such as process efficiency and footprint of the process processing module 20. Slots (not illustrated) provided to support an edge of the substrate are formed in the carrier 18. The slots are provided in a plurality in the third directions 16, and the substrates are located in a carrier to be stacked while being spaced apart from each other along the third directions 16. As the carrier 18, a Front Opening Unified Pod (FOUP) may be used.

The process processing module 20 may include a buffer unit 20, a transfer chamber 240, and process chambers 260 and 280. The transfer chamber 240 is disposed so that a longitudinal direction thereof is parallel to the first direction 12. The process chambers 260 and 280 are disposed on opposite sides of the transfer chamber 240 in the second direction 14. The process chambers 260 may be provided to be symmetrical to each other relative to the transfer chamber 240. Some of the process chambers 260 and 280 are disposed along the longitudinal direction of the transfer chamber 240. Additionally, some of the process chambers 260 and 280 are arranged to be stacked on top of each other. That is, the process chambers 240 may be disposed in an array of A×B (A and B are natural numbers equal to or greater than 1) on opposite sides of the transfer chamber 240. Here, A is the number of process chambers 260 and 280 provided in a line along the first direction 12, and B is the number of process chambers 260 and 280 provided in a line along the third direction 16. When four or six process chambers 260 are provided on each of the opposite sides of the transfer chamber 240, the process chambers 260 and 280 may be disposed in an array of 2×2 or 3×2. The number of process chambers 260 and 280 may be increased or decreased. Unlike the foregoing, the process chamber 260 may be provided only to one side of the transfer chamber 240. In addition, the process chambers 260 and 280 may be provided as a single layer on one side and the opposite sides of the transfer chamber 240. In addition, the process chambers 260 and 280 may be provided in various arrangements unlike the above.

The process chambers 260 and 280 of the present exemplary embodiment may be categorized as including a cleaning chamber and a drying chamber. In this case, the cleaning chamber may be a substrate processing facility for cleaning the substrate, which will be described below, and the drying chamber may be a substrate processing facility for drying the substrate.

The buffer unit 220 is disposed between the transfer frame 140 and the transfer chamber 240. The buffer unit 220 may provide a space in which the substrate W stays before the substrate W is transferred between the transfer chamber 240 and the transfer frame 140. The buffer unit 220 is provided with slots (not illustrated) in which the substrate W is placed therein, and the slots (not illustrated) are provided in plural to be spaced apart from each other along the third direction 16. In the buffer unit 220, a side facing the transfer frame 140 and a side facing the transfer chamber 240 are each open.

The transfer frame 140 transfers the substrate W between the carrier 18 seated at the load port 120 and the buffer unit 220. The transfer frame 140 is provided with an index rail 142 and an index robot 144. The index rail 142 is provided so that a longitudinal direction thereof is parallel to the second direction 14. The index robot 144 is installed on the index rail 142, and linearly moves in the second direction 14 along the index rail 142. The index robot 144 includes a base 144a, a body 144b, and an index arm 144c. The base 144a is installed to be movable along the index rail 142. The body 144b is coupled to the base 144a. The body 144b is provided to be movable in the third direction 16 on the base 144a. Further, the body 144b is provided to be rotatable on the base 144a. The index arm 144c is coupled to the body 144b and is provided to be movable forwardly and backwardly with respect to the body 144b. A plurality of index arms 144c is provided to be individually driven. The index arms 144c are disposed to be stacked in the state of being spaced apart from each other in the third direction 16. Some of the index arms 144c may be used when the substrate W is transferred from the process processing module 20 to the carrier 18, and another some of the plurality of index arms 144c may be used when the substrate W is transferred from the carrier 130 to the process processing module 20. This may prevent the particles generated from the substrate W before the process processing from being attached to the substrate W after the process processing in the process in which the index robot 144 loads and unloads the substrate W.

The transfer chamber 240 transfers the substrate W between the buffer unit 220 and the process chambers 260. A guide rail 242 and a main robot 244 are provided to the transfer chamber 240. The guide rail 242 is disposed so that a longitudinal direction thereof is parallel to the first direction 12. The main robot 244 is installed on the guide rail 242 and linearly moved along the first direction 12 on the guide rail 242. The main robot 244 includes a base 244a, a body 244b, and a main arm 244c. The base 244a is installed to be movable along the guide rail 242. The body 244b is coupled to the base 244a. The body 244b is provided to be movable in the third direction 16 on the base 244a. Further, the body 244b is provided to be rotatable on the base 244a. The main arm 244c is coupled to the body 244b, and provided to be movable forwardly and backwardly with respect to the body 244b.

Hereinafter, a substrate processing apparatus 300 provided in the process chamber 260 will be described. In the present exemplary embodiment, the case where the substrate processing apparatus 300 performs a liquid treating process on the substrate will be described as an example. The liquid treating process further includes a process of cleaning a substrate.

FIG. 2 is a cross-sectional view illustrating a substrate processing apparatus of FIG. 1. Referring to FIG. 2, the substrate processing apparatus 300 further includes a chamber 310, a processing container 320, a support unit 340, a lifting unit 360, a liquid discharge unit 400, an airflow formation unit 500, a liquid supply unit 600, and a controller 900. The chamber 310 provides a processing space 312 in which a process for processing the substrate W is performed.

The processing container 320 is positioned in the processing space 312 and is provided in the shape of a cup with an open top. When viewed from above, the processing container 320 is positioned to overlap an exhaust pipe. The processing container 320 includes an internal collection container 322 and an external collection container 326. Each of the collection containers 322 and 326 collects a different treatment solution from the treatment solutions used in the process. The internal collection container 322 is provided in the shape of an annular ring surrounding the support unit 340, and the external collection container 326 is provided in the shape of an annular ring surrounding the inner collection container 322. An inner space 322a of the internal collection container 322 and a space 326a between the external collection container 326 and the internal collection container 322 function as inlets for the treatment solution to flow into the internal collection container 322 and the external collection container 326, respectively. Collection lines 322b and 326b are connected to the bottom surfaces of the collection containers 322 and 326, respectively, to extend vertically in the down direction. Each of the collection lines 322b and 326b functions as a discharge pipe to discharge the treatment solution that has been introduced through the respective collection containers 322 and 326. The discharged treatment solution may be reused through an external treatment solution regeneration system (not illustrated).

The support unit 340 is provided as a substrate support unit 340 for supporting and rotating the substrate W. The support unit 340 is disposed within the processing container 320. The substrate support unit 340 supports the substrate W and rotates the substrate W during the process progress. The support unit 340 includes a spin chuck 342, a support pin 344, a chuck pin 346, and a rotation shaft 348. The spin chuck 342 has a top surface that is substantially circular when viewed from the top. The rotation shaft 348 that is rotatable by a driver is fixedly coupled to the bottom surface of the spin chuck 342. In one example, the driver may be formed of a motor 349. A plurality of support pins 344 is provided. The support pins 344 are spaced apart on the edge portion of a top surface of the spin chuck 342 and protrude upwardly from the spin chuck 342. The support pins 334 are arranged in combination with each other to have an overall annular ring shape. The support pin 344 supports an edge of the rear surface of the substrate W so that the substrate W is spaced apart from the top surface of the spin chuck 2631 at a predetermined distance. A plurality of chuck pins 346 is provided. The chuck pins 346 are disposed to be further away from a center of the spin chuck 342 than the support pins 344. The chuck pin 346 is provided to protrude upwardly from the spin chuck 342. The chuck pin 346 supports a lateral portion of the substrate W to prevent the substrate W from laterally deviating from its stationary position when the support unit 340 is rotated. The chuck pin 346 is provided to be linearly movable between a standby position and a support position along a radial direction of the spin chuck 342. The standby position is a position further away from the center of the spin chuck 342 relative to the support position. When the substrate W is loaded into or unloaded from the support unit 340, the chuck pin 346 is positioned in the standby position, and when a process is being performed on the substrate W, the chuck pin 346 is positioned in the support position. In the support position, the chuck pin 346 is in contact with the lateral portion of the substrate W.

The lifting unit 360 regulates the relative height between the processing container 320 and the support unit 340. The lifting unit 360 linearly moves the processing container 320 in the upper and lower directions. As the processing container 320 is moved up and down, the relative height of the processing container 320 with respect to the support unit 340 changes. The lifting unit 460 includes a bracket 360, a moving shaft 362, and a driver 364. The bracket 362 is fixedly installed on the outer wall of the processing container 320, and a moving shaft 364, which is moved in the vertical direction by a driver 366, is fixedly coupled to the bracket 364. When the substrate W is placed on the support unit 340 or lifted from the support unit 340, the processing container 320 is lowered so that the support unit 340 protrudes above the processing container 320. Furthermore, when the process is in progress, the height of the processing container 320 is regulated so that the treatment solution may flow into the preset collection containers 322 and 326 according to the type of treatment solution that has been supplied to the substrate W.

As described above, the lifting unit 360 may move the support unit 340 in the upper and lower directions instead of the processing container 320.

The liquid discharge unit 400 supplies various types of liquids to the substrate W. The liquid discharge unit 400 further includes a plurality of nozzles 410 to 430. Each nozzle is moved to a process position and a standby position by a nozzle position driver 440. A process position is defined herein as a position where the nozzles 410 to 430 are capable of discharging liquid onto the substrate W positioned within the processing container 320, and a standby position is defined as a position where the nozzles 410 to 430 are waiting outside of the process position. According to an example, the process position may be a position at which the nozzles 410 to 430 may supply a liquid to the center of the substrate W. For example, when viewed from above, the nozzles 410 to 430 may be moved linearly or axially to be moved between the process position and the standby position. The treatment solution discharged from the liquid discharge unit 400 to the substrate W may be a treatment solution for processing the substrate W. Additionally, in the standby position, a collection pipe 450 may be disposed below the third nozzle 430. The collection pipe 450 collects the treatment solution when the third nozzle 430 discharges the treatment solution for cleaning.

The plurality of nozzles 410 to 430 discharges different types of liquid. The treatment fluid discharged from the nozzles 410 to 430 may include at least one of a chemical, a rinse solution, a cleaning solution, and an organic solvent. Referring to the exemplary embodiment of FIG. 2, a first nozzle 410 may be a nozzle for discharging chemicals. For example, the chemical may be a liquid capable of etching a film formed on the substrate W or removing particles remaining on the substrate W. For example, a chemical may be a liquid that has the properties of strong acid. Specifically, the chemical may include sulfuric acid. Further, the second nozzle 420 may be a nozzle for dispensing a rinse solution. The rinse solution may be a solution capable of rinsing the chemicals remaining on the substrate W. For example, the rinse solution may be pure water. Further, the second nozzle 420 may be a nozzle that discharges a cleaning solution. The cleaning solution may be a solution that treats the support unit 340, the processing container 320, and the collection pipe 450 after processing the substrate W. For example, the cleaning solution may include a reducing agent capable of triggering oxidation-reduction reaction. Additionally, the third nozzle 430 may be a nozzle for discharging an organic solvent. The organic solvent may be provided as a liquid capable of displacing the residual rinse solution on the substrate W. The organic solvent may be a liquid having a low surface tension compared to the rinse solution. The organic solvent may be isopropyl alcohol (IPA) liquid.

The airflow forming unit 500 forms a downward airflow in the processing space 312. The airflow forming unit 500 supplies airflow from an upper portion of the chamber 310 and exhausts airflow from a lower portion of the chamber 310. The airflow forming unit 500 further includes an airflow supply unit 520 and an exhaust unit 540. The airflow supply unit 520 and the exhaust unit 540 are positioned facing each other in the vertical direction.

The airflow supply unit 520 supplies gas in the downward direction. The gas supplied from the airflow supply unit 520 may be air from which impurities are removed. The airflow supply unit 520 further includes a fan 522, an airflow supply line 524, a supply valve 528, and a filter 526. The fan 522 is installed on the ceiling surface of the chamber 310. When viewed from above, the fan 522 is positioned to face the processing container. The fan 522 may be positioned to provide air toward the substrate W positioned within the processing container. The airflow supply line 524 is connected to the fan 522 to supply air to the fan 522. A supply valve 528 is installed in the airflow supply line 524 to regulate the amount of airflow supplied. The filter 526 is installed in the airflow supply line 524 to filter the air. For example, the filter 526 may remove particles and moisture contained in the air.

The exhaust unit 540 exhausts the processing space 312. The exhaust unit 540 further includes an exhaust pipe 542, a pressure reducing member 546, and an exhaust valve 548. The exhaust pipe 542 is installed on the bottom surface of the chamber 310 and is provided as a pipe to exhaust the processing space 312. The exhaust pipe 542 is positioned such that the exhaust port faces upwardly. The exhaust pipe 542 is positioned such that the exhaust port is in communication with the interior of the processing container. That is, the top of the exhaust pipe 542 is located within the processing container. Accordingly, the downward airflow formed within the processing container is exhausted through the exhaust pipe 542.

The pressure reducing member 546 reduces pressure of the exhaust pipe 542. A negative pressure is formed in the exhaust pipe 542 by the pressure reducing member 546, which exhausts the processing container. The exhaust valve 548 is installed in the exhaust pipe 542 and opens and closes the exhaust port of the exhaust pipe 542. The exhaust valve 548 regulates the exhaust volume.

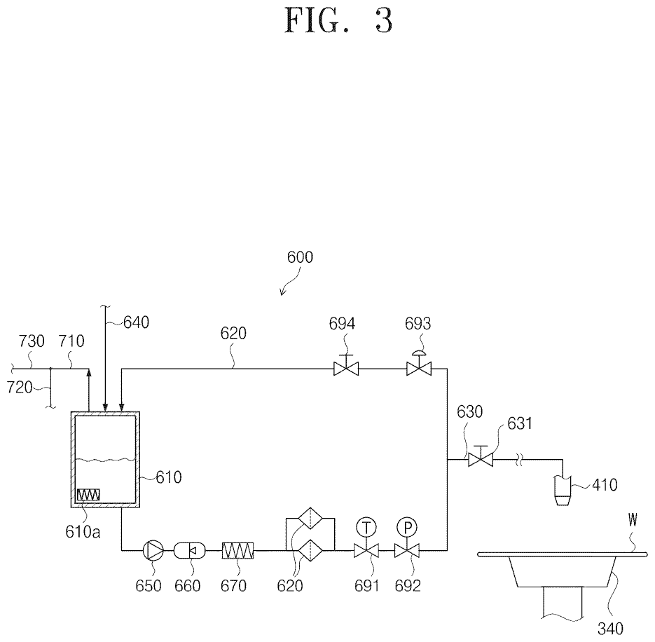

FIG. 3 is a diagram illustrating a liquid supply unit illustrated in FIG. 2 in more detail.

Referring further to FIG. 3, the liquid supply unit 600 supplies a treatment solution to the substrate processing apparatus 300, which performs a liquid treatment process on the substrate W. In this case, the liquid supply unit 600 may supply the treatment solution that performs a liquid treatment process on the substrate W in the heated state.

In one example of the liquid supply unit 600 for providing the treatment solution, the liquid supply unit 600 includes a tank 610, a liquid supply line 620, a branch line 630, a supplement line 640, a supply pump 650, an accumulator 660, a supply-side heater 670, a filter 680, a first valve 691, a second valve 692, a back pressure valve 693, and a third valve 694.

The tank 610 has an interior receiving space and has a predetermined volume. The tank 610 stores a treatment solution in the interior receiving space. In this case, the treatment solution may be an acidic chemical for etching the substrate W. For example, the chemical may include sulfuric acid. Further, the tank 610 may include a tank-side heater 610a that heats the treatment solution stored in the receiving space to a constant temperature. That is, the treatment solution stored in the receiving space may be maintained at a constant temperature by the tank-side heater 610a. In this case, the treatment solution may be heated by the tank-side heater 610a to a temperature of 100° C. or higher. Thus, the treatment solution may be vaporized to produce water-containing gas F1. For example, the water-containing gas F1 may be formed by sulfur trioxide fumes and moisture from the decomposition of sulfuric acid. The water-containing gas F1 is located in a vaporized state in the upper space of the treatment solution, which is in a liquefied state. This water-containing gas F1 is discharged through the vent line 710, which is to be described later.

The liquid supply line 620 allows the treatment solution stored in the tank 610 to be circulated. In one example, one side of the liquid supply line 620 may be connected to the bottom of the tank 610 and the other side may be connected to the top end of the tank 610.

The branch line 630 is branched from the liquid supply line 620 at one point. The branch line 630 may be branched after the rear end of the second valve 692 that is installed on the liquid supply line 620. The branch line 630 supplies the treatment solution to the process chamber 260. In one example, one side of the branch line 630 is connected to the liquid supply line 620 and the other side is connected to the process chamber 260. The branch line 630 may further be connected to a valve 631 for opening and closing operation, and the first nozzle 410 for spraying the treatment solution.

The supplement line 640 is connected to the receiving space of the tank 610. The supplement line 640 may be utilized as a line for supplementing the tank 610 with treatment solution supplied from an external source (not illustrated), another tank (not illustrated), or the like. In this case, the treatment solution supplemented via the supplement line 640 may be a regenerated treatment solution of the treatment solution used in the process chamber 260.

The supplement pump 650 is installed on the liquid supply line 620. The feed pump 650 pumps the treatment solution stored in the tank 610 and supplies the treatment solution into the liquid supply line 620.

The accumulator 660 is installed on the liquid supply line 620. The accumulator 660 may be disposed behind the supply pump 650. The accumulator 660 may assist power of the supply pump 650 and may serve to reduce the magnitude of pulsations that occur when the supply pump 650 is driven.

The supply-side heater 670 is installed on the liquid supply line 620. The supply-side heater 670 may be disposed behind the supply pump 650 or the accumulator 660. The supply-side heater 670 heats the treatment solution to the temperature required for the process.

The filter 680 is installed on the liquid supply line 620. The filter 680 may be disposed behind the supply-side heater 670. The filter 680 may be provided in a dual filter structure. The plurality of filter 680 may be provided in a parallel structure. The filter 680 filters particles contained in the treatment solution heated to the process temperature.

The first valve 691 is installed on the liquid supply line 620. The first valve 691 may be disposed behind the filter 680. The first valve 691 opens and closes the liquid supply line 620 to control the flow of the treatment solution. The first valve 691 may further include a thermometer or a pressure gauge.

The second valve 692 is installed on the liquid supply line 620. The second valve 692 may be disposed behind the first valve 691. The second valve 692 opens and closes the liquid supply line 620 to control the flow of the treatment solution. The second valve 692 may include a thermometer or a pressure gauge. When the first valve 691 includes a thermometer, the second valve 692 may include a pressure gauge.

The back pressure valve 693 is installed on the liquid supply line 620. The back pressure valve 693 may be disposed behind the second valve 692. The back pressure valve 693 maintains the treatment solution flowing in the liquid supply line 620 at a constant pressure after the branch point of the branch line 630.

The third valve 694 is installed on the liquid supply line 620. The third valve 694 may be disposed behind the back pressure valve 693. The third valve 694 opens and closes the liquid supply line 620 to control the flow of the treatment solution.

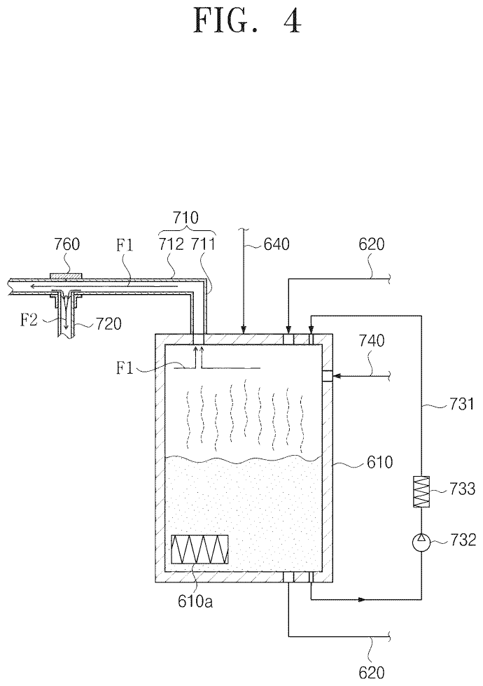

FIG. 4 is an enlarged view of the periphery of a tank illustrated in FIG. 3.

Referring further to FIG. 4, the liquid supply unit 600 may exhaust the water-containing gas F1 generated from the treatment solution heated in the tank 610.

As one example of the liquid supply unit 600 for exhausting the water-containing gas F1, the liquid supply unit 600 may further include a vent line 710, and a condensate discharge line 720.

The vent line 710 is connected at one end to the top end of the tank 610. In this case, the vent line 710 is disposed higher than the top end of the tank 610. Accordingly, the water-containing gas F1 may evaporate upwardly by vaporization and be discharged into the vent line 710. In this case, the other end of the vent line 710 may be connected to a line 730 of a collection unit (not illustrated) that recycles the water-containing gas F1 or treats wastewater. Here, the water-containing gas F1 is generated by heating and vaporization of the treatment solution remaining in the tank 610 as described above, and may act as a factor in producing condensate F2, which is to be described later, upon recondensation. The water-containing gas F1 may be located in a vaporized state in the upper space of the treatment solution present within the tank 610 in a liquefied state.

In this case, the vent line 710 may include a first region 711 that has one end connected to the tank 610 and is perpendicular to the direction of the upper end of the tank 610, and a second region 712 that extends from the first region 711 and extends toward the direction of a lateral surface of the tank 610. In this case, the second region 712 of the condensate outlet line 720 may be connected upwardly from the top surface of the tank 610. Accordingly, the water-containing gas F1 may be discharged laterally through the second region 712 while being discharged vertically through the first region 711. In this case, the water-containing gas F1 may recondense under the influence of outside air or under the influence of a temperature difference when being exhausted through the vent line 710 to produce the condensate F2. In this case, the condensate F2 may be formed including water. In some cases, the condensate F2 may further include a sulfur trioxide component or other acidic components or particulate components. The condensate F2 is formed primarily due to the temperature influence of the vent line 710 in the process of discharging the water-containing gas F1 along the vent line 710, and may form droplets around the vent lint 710 and the upper inner surface of the tank 610 to which the vent line 710 is connected. The condensate F2 that forms droplets around the vent line 710 or the upper inner surface of the tank 610 may act as a source of contamination of the treatment fluid remaining in the tank 610 when the condensate F2 it falls into the tank 610 in a particle-containing state.

The condensate discharge line 720 is connected at one end to the vent line 710. Furthermore, the other end of the condensate discharge line 720 may be connected to a collection unit (not illustrated) or a collection tank (not illustrated) for collecting the condensate F2 for recycling or wastewater treatment. The condensate discharge line 720 discharges the condensate F2 that is generated when the moisture contained in the water-containing gas F1 recondenses in the process of discharging the water-containing gas F1 from the vent line 710. Thus, the condensate F2 generated when the water-containing gas F1 is discharged through the vent line 710 is discharged through the condensate discharge line 720 rather than pooling around the vent line 710 and the upper inner surface of the tank 610, thereby minimizing contamination of the treatment solution inside the tank 610 by the condensate F2.

Further, the condensate discharge line 720 may be connected to the second region 712 of the vent line 710 extending in the lateral direction of the tank 610, and may be disposed facing in the lower direction of the second region 712. Thus, the water-containing gas F1 may be discharged into the vent line 710 and the condensate F2 may be discharged through the condensate discharge line 720.

In this case, the top end of the condensate discharge line 720 may be disposed lower than the top end of the vent line 710 in order to facilitate discharge the condensate F2 generated by recondensation of the water-containing gas F1 without being introduced into the treatment solution side of the tank 610. Thus, the condensate F2 generated by recondensation of the water-containing gas F1 flowing into the vent line 710 may be condensed and discharged into the condensate discharge line 720, which is lower than the vent line 710.

In the meantime, the point at which the vent line 710 and the condensate drain line 720 are connected to each other may be connected by welding the joint portion of the vent line 710 and the condensate discharge line 720, or may be connected by a branch connection member 760. However, in the present invention, the method of connecting the vent line 710 and the condensate drain line 720 each other is not limited to the above examples, and the method may be implemented into various connection methods as a matter of course.

The liquid supply unit 600 may further include a circulation line 731, a circulation pump 732, and a heater 733 for circulation.

Both ends of the circulation line 731 are connected to the tank 610. For example, one end of the circulation line 731 may be connected to the bottom surface of the tank 610 and the other end thereof may be connected to the top surface of the tank 610. The circulation line 731 serves as a pathway for purifying the treatment solution inside the tank 610.

The circulation pump 732 is installed on the circulation line 731. The circulation pump 732 circulates the treatment solution in the tank 610 in the circulation line 731.

The circulation heater 733 is installed on the circulation line 731. The heater 733 for circulation heats the treatment solution circulating in the circulation line 731 to a temperature suitable for treatment of the substrate W.

Here, the treatment solution may be simultaneously heated by the tank-side heater 610a or the heater 733 for circulation described above, and may be heated by at least one of the tank-side heater 610a or the heater 733 for circulation.

The liquid supply unit 600 may further include a gas supply line 740.

One end of the gas supply line 740 may be connected to the tank 610 and the other end thereof may be connected to a gas supply source (not illustrated). The gas supply line 740 may supply the tank 610 with gas, including nitrogen gas or inert gas. The gas supplied from the gas supply line 740 to the tank 610 may be supplied to the interior of the tank 610 to increase the pressure inside the tank 610, thereby preventing the treatment solution from pulsating during circulation. Additionally, the gas supplied to the tank 610 from the gas supply line 740 may be exhausted to the vent line 710 along with the water-containing gas F1. In this case, the gas supplied from the gas supply line 740 to the tank 610 may be supplied in a heated state. In this case, the gas supplied from the gas supply line 740 to the tank 610 may be formed at a temperature equal to or higher than the temperature of the treatment solution, such that the temperature of the water-containing gas F1 is not significantly different from the temperature of the treatment solution. Thus, the temperature of the water-containing gas F1 is maintained at a temperature similar to the temperature of the treatment solution by the gas in the gas supply line 740, thereby minimizing the formation of the condensate F2 when the water-containing gas F1 is discharged from the tank 610 to the vent line 710. In this case, the gas supplied to the tank 610 from the gas supply line 740 may include nitrogen gas or inert gas, as described above, to avoid chemical reactions with the treatment solution.

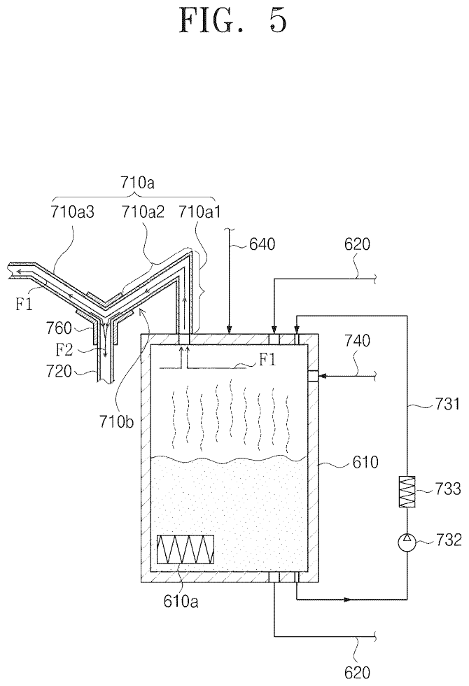

FIG. 5 is a diagram illustrating a modified example of the vent line and the condensate discharge line illustrated in FIG. 4.

Referring further to FIG. 5, the liquid supply unit 600 includes a vent line 710a having a different shape from the vent line 710 described above, and a condensate discharge line 720, and the other configurations are configured identically to those in the previous exemplary embodiments.

In the present exemplary embodiment, the vent line 710a may discharge the water-containing gas F1, as described above, and may discharge gas supplied from the gas supply line 740.

In this case, the vent line 710a is formed to further include a downwardly protruding region 710b that decreases in height as it goes downstream and subsequently increases in height as it goes downstream. Downstream is the direction from the point where the vent line 710a is connected to the tank 610 to the point where the condensate discharge line 720 is connected to the vent line 710a. In this case, the condensate discharge line 720 is connected to the downwardly protruding region 710b to discharge the condensate F2 generated in the vent line 710a. Thus, the condensate F2 generated in the vent line 710a may flow through the downwardly protruding region 710b of the vent line 710a and be easily discharged into the condensate discharge line 720. In this case, the condensate discharge line 720 is connected to the vent line 710a at the region having the lowest height in the downwardly protruding region 710b, such that the condensate may be discharged without remaining in the condensate discharge line 720.

As one example of the vent line 710a, the vent line 710a may include a first line 710al, a second line 710a2, and a third line 710a3.

The first line 710al is connected upwardly from the top surface of the tank 610.

The second line 710a2 extends from the first line 710al in a lateral direction of the tank 610 and is formed to be inclined downwardly toward the downstream. The first line 710al and the second line 710a2 may be provided with the downwardly protruding region 710b described above.

The third line 710a3 extends from the second line 710a2 in the lateral direction of the tank 610 and is formed to be inclined upwardly toward the downstream.

In this case, the condensate discharge line 720 is connected to the vent line 710a at the point where the second line 710a2 and the third line 710a3 are connected.

Thus, the condensate F2 generated in the vent line 710a may flow along the inclined inner surfaces of the second line 710a2 and the third line 710a3 and be easily discharged into the condensate discharge line 720.

Hereinafter, a gas discharge method of discharging the water-containing gas F1 generated in the process of supplying the treatment solution of the substrate processing apparatus as described above will be described.

The gas discharge method proceeds in a state in which the treatment solution for processing the substrate W is heated by the tank side heater 610a or the circulation heater 733 as described above. In this case, the water-containing gas F1 is generated in the interior of the tank 610 by vaporization of the treatment solution as described above, and the water-containing gas F1 is discharged to the exterior of the tank 610. For example, the water-containing gas F1 may be discharge by connecting the vent line 710 to the tank 610 as described above. In this case, the treatment solution may contain water or chemical components or particles, depending on the type of chemical, as described above.

In this case, in the process of discharging the water-containing gas F1, the water-containing gas F1 recondenses due to temperature differences or composition differences to produce the condensate F2, and by discharging the condensate F2 generated by the recondensation of the water-containing gas F1 in a path different from the path through which the water-containing gas F1 is discharged, the inflow of the condensate F2 to the treatment solution side of the tank 610 may be minimized. In this case, the path through which the condensate F2 is discharged may be located at a lower position than the path through which the water-containing gas F1 is discharged, so that the condensate F2 may be discharged in a state of being collected at a single point.

Further, at least a portion of the path through which the water-containing gas F1 is discharged may be formed in a lateral direction, and the path through which the condensate F2 is discharged may be provided to head downstream of the path through which the water-containing gas F1 is discharged. For example, as described above, the condensate outlet line 720 may be provided to head downwardly in the second region 712 disposed in the lateral direction of the tank 610 to allow the condensate F2 to be collected toward the condensate outlet line 720. In another example, as described above, the condensate discharge line may be connected to the downwardly protruding region to discharge the condensate F2.

Thus, the water-containing gas F1 is minimized from entering the interior of the tank 610, so that the treatment solution inside the tank 610 is minimally contaminated by the condensate F2.

On the other hand, in the water-containing gas discharge method, in order to minimize the generation of the condensate F2 generated by the water-containing gas F1, the water-containing gas F1 may be mixed with gas having a temperature equal to or higher than the temperature of the treatment solution when the water-containing gas F1 is discharged. For example, as described above, a gas supply line 740 may be connected to the tank 610, and gas containing nitrogen gas or inert gas may be supplied through the gas supply line 740, and in this case, the temperature of the gas is the same as or higher than the temperature of the treatment solution. Thus, the water-containing gas F1 may be discharged with minimal generation of condensate F2 because the temperature does not drop near where the water-containing gas F1 begins to be discharged, thereby minimizing contamination of the treatment solution by the condensate F2.

On the other hand, the liquid supply unit including the vent lines 710 and 710a and condensate discharge line 720 as described above may be provided to various forms of substrate processing apparatus.

For example, the liquid supply unit including the vent lines 710 and 710a and the condensate discharge line 720 may be utilized to process the substrate W by using a different type of treatment solution, such as phosphoric acid.

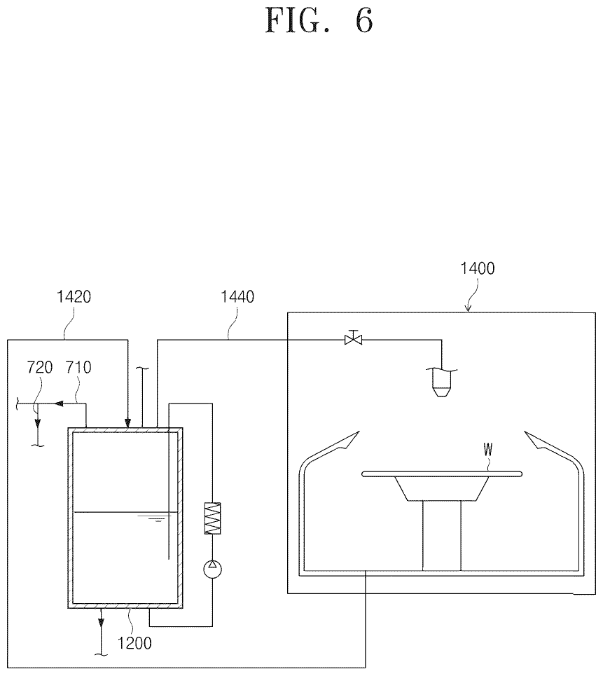

Accordingly, referring further to FIG. 6, FIG. 6 is a diagram schematically illustrating a substrate processing apparatus for treating the substrate W by using phosphoric acid.

As illustrated in FIG. 6, a substrate processing apparatus by using phosphoric acid as a treatment solution may include a phosphoric acid tank 1200 for storing phosphoric acid that is a treatment solution, a phosphoric acid supply line 1440 for supplying phosphoric acid stored in the phosphoric acid tank 1200, a liquid treatment chamber 1400 for treating the substrate W by discharging phosphoric acid discharged from the phosphoric acid supply line 1440 into a nozzle, and a phosphoric acid collection line 1420 for collecting the phosphoric acid discharged from the liquid treatment chamber 1400.

In this case, the phosphoric acid tank 1200 may further include the vent line 710 and condensate discharge line 720 of the exemplary embodiment described above to facilitate discharge of the condensate.

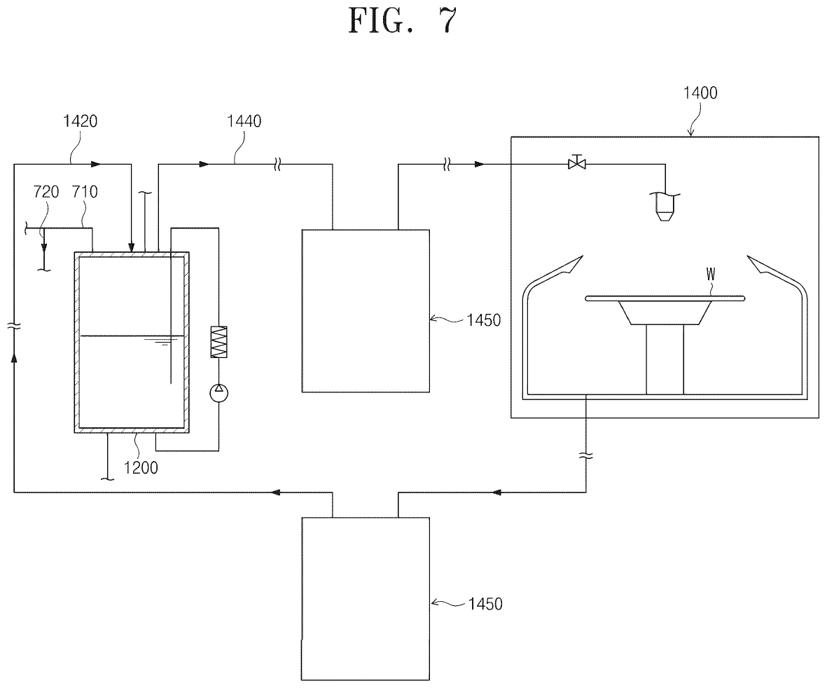

In this case, as illustrated in FIG. 7, the substrate processing apparatus may further include a phosphoric acid buffer tank 1450 in each of the phosphoric acid supply line 1440 and the phosphoric acid collection line 1420 of the aforementioned exemplary embodiment.

In the example described above, the present invention has been described based on the case where the treatment solution stored in the tank 1200 is an aqueous solution of phosphoric acid as an example. However, the treatment solution stored in the tank 1200 may be any other type of treatment solution that includes water and whose concentration is controlled by evaporation of the water.

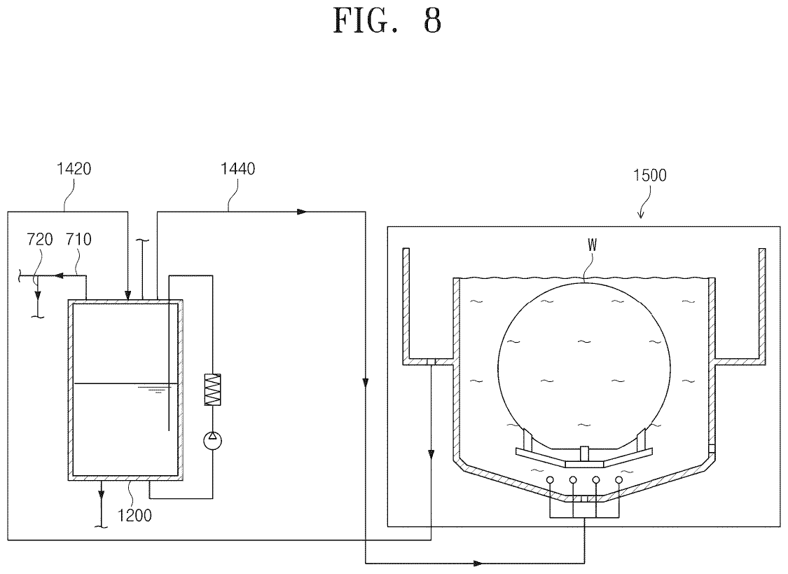

Furthermore, while the substrate processing apparatus has been described above as a sheet-fed type apparatus in which the liquid treatment chamber 1400 sprays a treatment solution through a nozzle to liquid treat a single sheet of substrate W, the liquid treatment chamber 1500, as illustrated in FIG. 8, may also be provided in a batch type in which a plurality of substrates W are immersed in the treatment solution simultaneously.

As described above, the present invention has been described with reference to the specific matters, such as a specific component, limited exemplary embodiments, and drawings, but these are provided only for helping general understanding of the present invention, and the present invention is not limited to the aforementioned exemplary embodiments, and those skilled in the art will appreciate that various changes and modifications are possible from the description.

Therefore, the spirit of the present invention should not be limited to the described exemplary embodiments, and it will be the that not only the claims to be described later, but also all modifications equivalent to the claims belong to the scope of the present invention.

What is claimed is:

1. An apparatus for processing a substrate, the apparatus comprising:
a chamber having a processing space for processing a substrate;
a support unit disposed in the processing space and for supporting the substrate;
a liquid discharge unit for supplying a treatment solution to the substrate and processing the substrate when processing the substrate; and
a liquid supply unit for supplying a treatment solution to the liquid discharge unit,
wherein the liquid supply unit includes:
a tank for storing the treatment solution;
a liquid supply line for supplying the treatment solution in the tank to the liquid discharge unit;
a vent line connected to the tank to discharge water-containing gas in the tank;
a heater for heating the treatment solution in the tank or the treatment solution circulating from the tank; and
a condensate discharge line connected to the vent line and for discharging condensate generated from the water-containing gas.

2. The apparatus of claim 1, wherein the vent line further includes a downwardly protruding region that decreases in height as it goes downstream and subsequently increases in height as it goes downstream, and
the condensate discharge line is connected to the vent line in the downwardly protruding region.

3. The apparatus of claim 2, wherein the condensate discharge line is connected to the vent line in a region having the lowest height in the downwardly protruding region.

4. The apparatus of claim 1, wherein the vent line includes:
a first line connected to the tank;
a second line extending from the first line and inclined downwardly in a downstream direction; and
a third line extending from the second line and inclined upwardly in a downstream direction, and
the condensate discharge line is connected to the vent line at a point where the second line and the third line are connected.

5. The apparatus of claim 4, wherein the first line is connected to the tank so as to extend upwardly from a top surface of the tank.

6. The apparatus of claim 1, wherein the liquid supply unit further includes a gas supply line for supplying gas containing nitrogen gas or inert gas to the tank.

7. The apparatus of claim 6, wherein the gas supplied to the tank from the gas supply line is in a heated state.

8. The apparatus of claim 7, wherein the gas supplied to the tank from the gas supply line has a temperature equal to or higher than a temperature of the treatment solution.

9. The apparatus of claim 1, wherein the treatment solution includes a chemical diluted with water.

10. The substrate treating apparatus of claim 9, wherein the chemical is sulfuric acid or phosphoric acid.

11. A treatment solution supply unit for supplying a treatment solution to process a substrate, the treatment solution supply unit comprising:
a tank for storing the treatment solution;
a liquid supply line for supplying a treatment solution in the tank to a liquid discharge unit;
a vent line connected to the tank to discharge water-containing gas in the tank;
a heater for heating the treatment solution in the tank or the treatment solution circulating from the tank; and
a condensate discharge line connected to the vent line to discharge condensate generated from the water-containing gas.

12. The treatment solution supply unit of claim 11, wherein the vent line further includes a downwardly protruding region that decreases in height as it goes downstream and subsequently increases in height as it goes downstream, and
the condensate discharge line is connected to the vent line in the downwardly protruding region.

13. The treatment solution supply unit of claim 12, wherein the condensate discharge line is connected to the vent line in a region having the lowest height in the downwardly protruding region.

14. The treatment solution supply unit of claim 11, wherein the vent line includes:
a first line connected to the tank;
a second line extending from the first line and inclined downwardly toward a downstream direction; and
a third line extending from the second line and inclined upwardly in a downstream direction, and
the condensate discharge line is connected to the vent line at a point where the second line and the third line are connected.

15. The treatment solution supply unit of claim 14, wherein the first line is connected to the tank so as to extend upwardly from a top surface of the tank.

16. The treatment solution supply unit of claim 11, further comprising:
a gas supply line for supplying gas containing nitrogen gas or inert gas to the tank.

17. The treatment solution supply unit of claim 16, wherein the gas supplied to the tank from the gas supply line is in a heated state.

18. The treatment solution supply unit of claim 11, wherein the treatment solution includes a chemical diluted with water.

19. The treatment solution supply unit of claim 18, wherein the chemical is sulfuric acid or phosphoric acid.

20. An apparatus for processing a substrate, the apparatus comprising:
a chamber having a processing space for processing a substrate;
a support unit disposed in the processing space and for supporting the substrate;
a liquid discharge unit for supplying a treatment solution to the substrate and processing the substrate when processing the substrate; and
a liquid supply unit for supplying a treatment solution to the liquid discharge unit,
wherein the liquid supply unit includes:
a tank for storing the treatment solution;
a liquid supply line for supplying the treatment solution in the tank to the liquid discharge unit;
a vent line connected to the tank to discharge water-containing gas in the tank;
a heater for heating the treatment solution in the tank or the treatment solution circulating from the tank; and
a condensate discharge line connected to the vent line to discharge condensate generated from the water-containing gas,
the treatment solution is a liquid containing a chemical and moisture, and
the vent line includes:
a first line connected to the tank;
a second line extending from the first line and inclined downwardly toward a downstream direction; and
a third line extending from the second line and inclined upwardly in a downstream direction, and
the condensate discharge line is connected to the vent line at a point where the second line and the third line are connected.
